(19) United States
(12) Patent Application Publication
(10) Pub. No.: US 2022/0352127 A1
(43) Pub. Date: Nov. 3, 2022

(54) LIGHT-EMITTING MODULE AND DISPLAY DEVICE

(71) Applicant: Optoma Corporation, New Taipei City (TW)

(72) Inventors: Cheng-Chien Ou, Hsin-Chu (TW); Chia Yu Li, Hsin-Chu (TW); Shih-Hung Hsu, Hsin-Chu (TW); Kuo-Yuan Hung, Hsin-Chu (TW)

(73) Assignee: Optoma Corporation, New Taipei City (TW)

(21) Appl. No.: 17/715,043

(22) Filed: Apr. 7, 2022

(30) Foreign Application Priority Data
Apr. 29, 2021 (CN) 202110471452.8

(51) Int. Cl. H01L 25/075; H01L 33/62; F21V 23/00

(52) U.S. Cl. CPC H01L 25/0753; H01L 33/62; F21V 23/005; H01L 25/167

(57) ABSTRACT

A light-emitting module including multiple light-emitting units and a display device are provided. Each of the light-emitting units includes multiple light-emitting elements. Each of the light-emitting elements includes a first end and a second end. The first ends of the light-emitting elements of a first light-emitting unit and a second light-emitting unit among the light-emitting units are electrically interconnected. The first ends of the light-emitting elements of a third light-emitting unit and a fourth light-emitting unit among the light-emitting units are electrically interconnected. The second end of one of the light-emitting elements of the first light-emitting unit and the second end of one of the light-emitting elements of the corresponding third light-emitting unit are electrically interconnected. The second end of one of the light-emitting elements of the second light-emitting unit and the second end of one of the light-emitting elements of the corresponding fourth light-emitting unit are electrically interconnected.

### CROSS-REFERENCE TO RELATED APPLICATION

This application claims the priority benefit of China application serial no. 202110471452.8, filed on Apr. 29, 2021. The entirety of the above-mentioned patent application is hereby incorporated by reference herein and made a part of this specification.

### BACKGROUND

### Technical Field

The disclosure relates to an optical module and an optical device, and in particular, to a light-emitting module and a display device with the light-emitting module.

### Description of Related Art

As technology advances rapidly, display devices have gradually become an indispensable part of our daily lives. Generally, in light-emitting diode display screens, the pins of the light-emitting diodes are assembled and welded to a printed circuit board (PCB) with surface-mount technology (SMT). However, in the conventional design of light-emitting diode display screens, damage of the pins of the light-emitting diodes caused by solder cracks and collisions during assembly and operation cannot be solved. When light-emitting diode display screens are damaged due to collisions or solder cracks, they can only be repaired passively by disassembling the printed circuit boards and the light-emitting diodes.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The disclosure is directed to a light-emitting module which enhances the protection to reduce the rate of pixel malfunctioning and the repair rate.

A display device including the light-emitting module is provided in the disclosure.

Other objectives and advantages of the invention will be further understood from the further technological features disclosed by the embodiments of the disclosure.

To achieve one of, a part of, or all of the objectives above or other objectives, an embodiment of the disclosure provides a light-emitting module including multiple light-emitting units. Each of the light-emitting units includes multiple light-emitting elements. Each of the light-emitting elements includes a first end and a second end. The first ends of the light-emitting elements of a first light-emitting unit and a second light-emitting unit among the light-emitting units are electrically interconnected. The first ends of the light-emitting elements of a third light-emitting unit and a fourth light-emitting unit among the light-emitting units are electrically interconnected. The second end of one of the light-emitting elements of the first light-emitting unit and the second end of one of the light-emitting elements of the corresponding third light-emitting unit are electrically interconnected. The second end of one of the light-emitting elements of the second light-emitting unit and the second end of one of the light-emitting elements of the corresponding fourth light-emitting unit are electrically interconnected.

To achieve one of, a part of, or all of the objectives above or other objectives, an embodiment of the disclosure provides a display device including a drive substrate and multiple light-emitting modules. The light-emitting modules are configured on the drive substrate and electrically connected to the drive substrate. Each of the light-emitting modules includes multiple light-emitting units. Each of the light-emitting units includes multiple light-emitting elements. Each of the light-emitting elements includes the first end and the second end. The first ends of the light-emitting elements of the first light-emitting unit and the second light-emitting unit among the light-emitting units are electrically interconnected. The first ends of the light-emitting elements of the third light-emitting unit and the fourth light-emitting unit among the light-emitting units are electrically interconnected. The second end of one of the light-emitting elements of the first light-emitting unit and the second end of one of the light-emitting elements of the corresponding third light-emitting unit are electrically interconnected. The second end of one of the light-emitting elements of the second light-emitting unit and the second end of one of the light-emitting elements of the corresponding fourth light-emitting unit are electrically interconnected.

In light of the above, the embodiment of the disclosure has at least one of the following advantages or effects. In the design of the light-emitting modules of the disclosure, each of the light-emitting units of the light-emitting modules is protected by two-way circuits with the design of the first ends of the light-emitting elements of the first light-emitting unit and the second light-emitting unit among the light-emitting units being electrically interconnected, the first ends of the light-emitting elements of the third light-emitting unit and the fourth light-emitting unit among the light-emitting units being electrically interconnected, the second end of one of the light-emitting elements of the first light-emitting unit and the second end of one of the light-emitting elements of the corresponding third light-emitting unit being electrically interconnected, and the second end of one of the light-emitting elements of the second light-emitting unit and the second end of one of the light-emitting elements of the corresponding fourth light-emitting unit being electrically interconnected. Hence, when one of the two different sets of light-emitting units connected to the same electrode is damaged, the overall functionality of the light-emitting modules remains unaffected. Accordingly, the protection of the light-emitting modules of the disclosure is enhanced so as to reduce the rate of pixel malfunctioning and effectively reduce the repair rate.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of light-emitting modules of a display device according to an embodiment of the disclosure.

FIG. 2A is a schematic circuit diagram of the light-emitting modules of the display device in FIG. 1.

FIG. 2B is a schematic circuit diagram of light-emitting modules of a display device according to another embodiment of the disclosure.

FIG. 3 is a schematic bottom view of the light-emitting modules of the display device in FIG. 1.

FIG. 4 is a schematic view of the driving chip and the drive substrate of the display device in FIG. 1.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

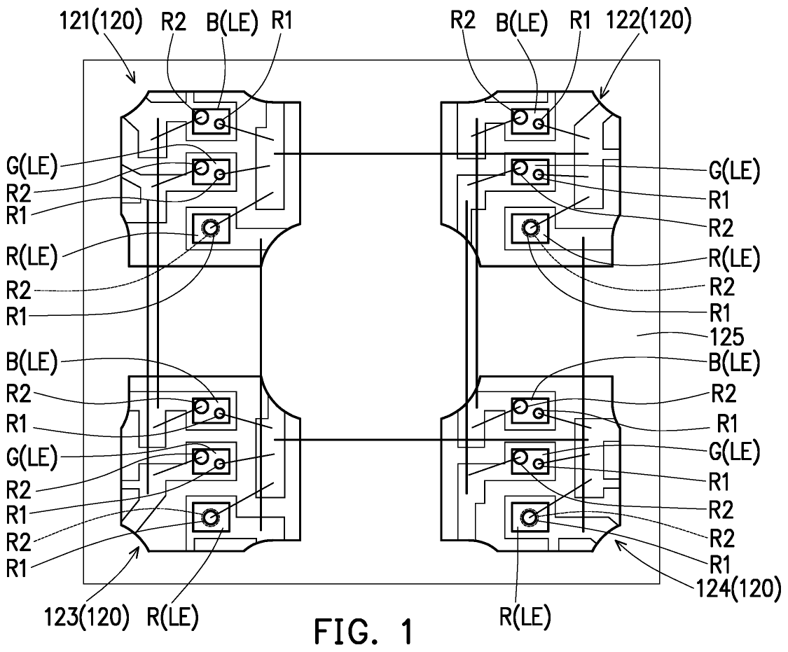

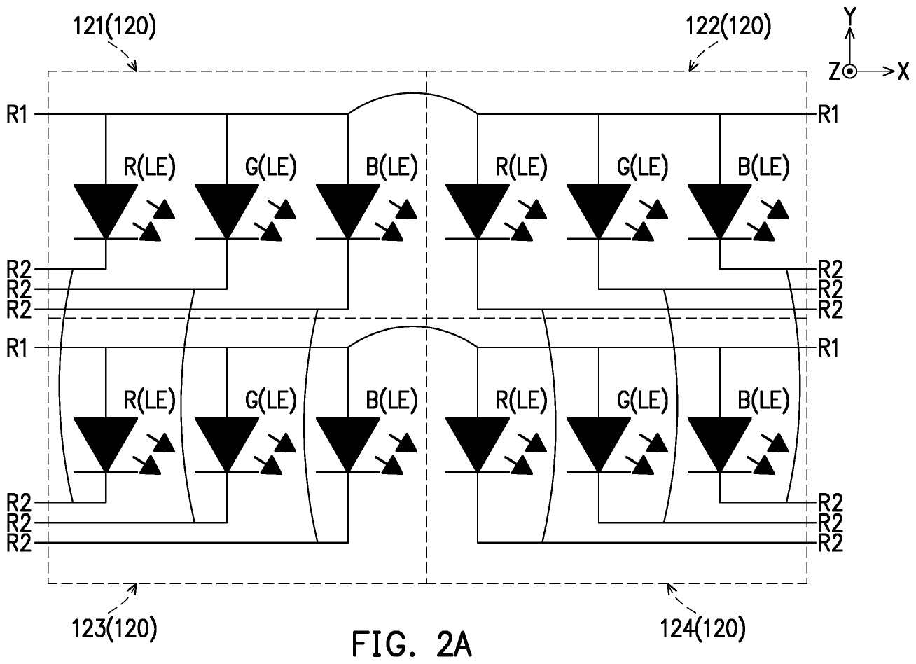

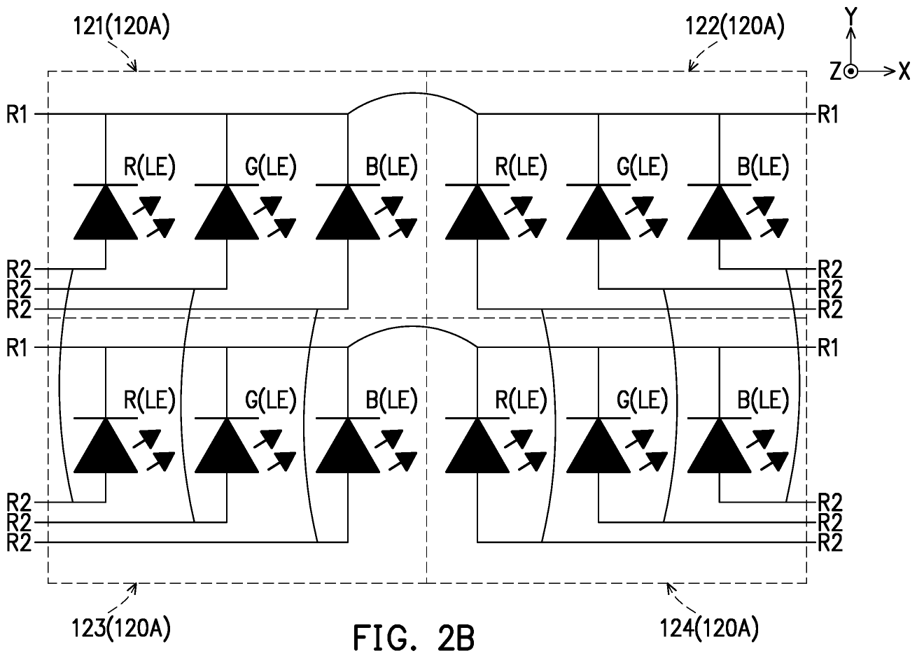

FIG. 1 is a schematic top view of light-emitting modules of a display device according to an embodiment of the disclosure. FIG. 2A is a schematic circuit diagram of the light-emitting modules of the display device in FIG. 1. FIG. 2B is a schematic circuit diagram of light-emitting modules of a display device according to another embodiment of the disclosure. The rectangular coordinates X-Y-Z are provided to describe the elements below. Note that to clearly describe the structure of a light-emitting module 120, only one of multiple light-emitting modules 120 of a display device 100 is illustrated in a schematic view and a part of the elements are omitted.

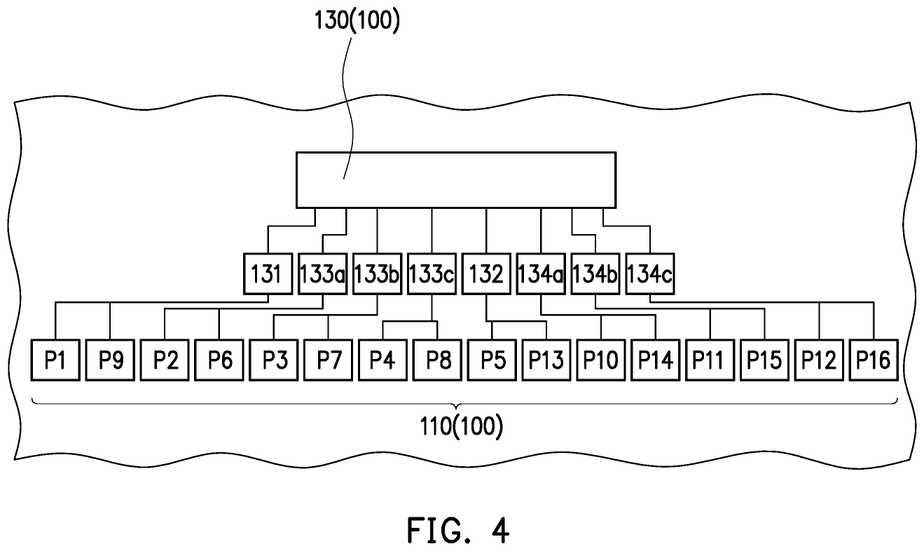

Referring to FIG. 1, FIG. 2A, and FIG. 4 together, in the embodiment, the display device 100 includes a drive substrate 110 and the light-emitting modules 120. The light-emitting modules 120 are configured on the drive substrate 110 and electrically connected to the drive substrate 110. Here, the drive substrate 110 is, for example but not limited to, a printed circuit board. The light-emitting modules 120 include multiple light-emitting units (i.e. a first light-emitting unit 121, a second light-emitting unit 122, a third light-emitting unit 123, and a fourth light-emitting unit 124). Each of the light-emitting units includes multiple light-emitting elements LE. Each of the light-emitting elements LE includes a first end R1 and a second end R2. The first ends R1 of the light-emitting elements LE of the first light-emitting unit 121 and the second light-emitting unit 122 among the light-emitting units are electrically interconnected. The first ends R1 of the light-emitting elements LE of the third light-emitting unit 123 and the fourth light-emitting unit 124 among the light-emitting units are electrically interconnected. The second end R2 of one of the light-emitting elements LE of the first light-emitting unit 121 and the second end R2 of one of the light-emitting elements LE of the corresponding third light-emitting unit 123 are electrically interconnected. The second end R2 of one of the light-emitting elements LE of the second light-emitting unit 122 and the second end R2 of one of the light-emitting elements LE of the corresponding fourth light-emitting unit 124 are electrically interconnected.

Specifically, in the embodiment, the first light-emitting unit 121 includes the three light-emitting elements LE and the three light-emitting elements LE are respectively a red light-emitting diode R, a green light-emitting diode G, and a blue light-emitting diode B emitting light with different colors. Each of the light-emitting elements LE includes the first end R1 and the second end R2, and the first end R1 of each of the light-emitting elements LE is electrically connected to each other in parallel. That is, the first end R1 of the red light-emitting diode R, the first end R1 of the green light-emitting diode G, and the first end R1 of the blue light-emitting diode B are electrically connected in parallel. In the same way, the second light-emitting unit 122, the third light-emitting unit 123, and the fourth light-emitting unit 124 all respectively include the three light-emitting elements LE and the three light-emitting elements LE are respectively the red light-emitting diode R, the green light-emitting diode G, and the blue light-emitting diode B emitting light with different colors. Each of the light-emitting elements LE includes the first end R1 and the second end R2, and the first end R1 of each of the light-emitting elements LE is electrically connected to each other in parallel. Note that the first light-emitting unit 121, the second light-emitting unit 122, the third light-emitting unit 123, and the fourth light-emitting unit 124 here are realized as a packaged structure in which each of the light-emitting elements LE of each of the light-emitting units is electrically connected to a carrier board 125 (e.g. a lead frame), for example, through wire bonding.

Furthermore, in the embodiment, the first end R1 of each of the light-emitting elements LE of the first light-emitting unit 121 and the first end R1 of each of the light-emitting elements LE of the second light-emitting unit 122 are electrically connected to each other in parallel. The first end R1 of each of the light-emitting elements LE of the third light-emitting unit 123 and the first end R1 of each of the light-emitting elements LE of the fourth light-emitting unit 124 are electrically connected to each other in parallel. In the first light-emitting unit 121 and the third light-emitting unit 123, the second end R2 of each of the light-emitting elements LE emitting light with the same color is electrically connected to each other in parallel. In the second light-emitting unit 122 and the fourth light-emitting unit 124, the second end R2 of each of the light-emitting elements LE emitting light with the same color is electrically connected to each other in parallel. That is, as shown in FIG. 2A, the second end R2 of the red light-emitting diode R, the second end R2 of the green light-emitting diode G, and the second end R2 of the blue light-emitting diode B of the first light-emitting unit 121 are respectively electrically connected to the second end R2 of the red light-emitting diode R, the second end R2 of the green light-emitting diode G, and the second end R2 of the blue light-emitting diode B of the third light-emitting unit 123 in parallel. The second end R2 of the red light-emitting diode R, the second end R2 of the green light-emitting diode G, and the second end R2 of the blue light-emitting diode B of the second light-emitting unit 122 are respectively electrically connected to the second end R2 of the red light-emitting diode R, the second end R2 of the green light-emitting diode G, and the second end R2 of the blue light-emitting diode B of the fourth light-emitting unit 124 in parallel.

Here, as shown in FIG. 2A, the first light-emitting unit 121 and the second light-emitting unit 122 are adjacently configured (configured in parallel to the X axis), and an arrangement direction of the first light-emitting unit 121 and the third light-emitting unit 123 is parallel to an arrangement direction of the second light-emitting unit 122 and the fourth light-emitting unit 124 (arranged in parallel to the Y axis). The first end R1 of each of the light-emitting elements LE is specifically a p-electrode, and the second end R2 of each of the light-emitting elements LE is specifically an n-electrode. In other words, a circuit design of the light-emitting modules 120 as shown in FIG. 2A of the embodiment is specifically common anode. In another embodiment, referring to FIG. 2B, the first end R1 of each of the light-emitting elements LE is specifically an n-electrode, and the second end R2 of each of the light-emitting elements LE is specifically a p-electrode. That is, a circuit design of light-emitting modules 120A is specifically common cathode, which is still included in the scope of the disclosure.

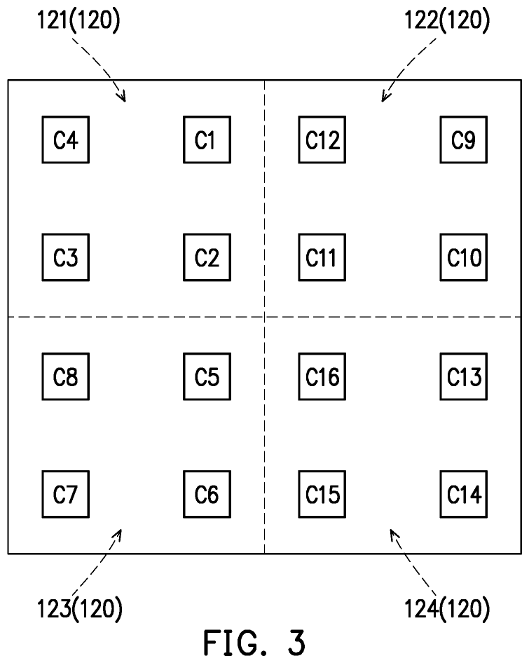

Referring to FIG. 3 and FIG. 4 together, FIG. 3 is a schematic bottom view of the light-emitting modules of the display device in FIG. 1. FIG. 4 is a schematic view of the driving chip and the drive substrate of the display device in FIG. 1. In the embodiment, the display device 100 further includes a driving chip 130. The driving chip 130 includes a first pin 131, a second pin 132, three third pins 133a, 133b, and 133c, and three fourth pins, 134a, 134b, and 134c. The drive substrate 110 of the embodiment includes multiple pads P1, P2, P3, P4, P5, P6, P7, P8, P9, P10, P11, P12, P13, P14, P15, and P16. Each of the first light-emitting unit 121, the second light-emitting unit 122, the third light-emitting unit 123, and the fourth light-emitting unit 124 respectively corresponds to four pads among the pads P1, P2, P3, P4, P5, P6, P7, P8, P9, P10, P11, P12, P13, P14, P15, and P16. For example, the first light-emitting unit 121 corresponds to the pads P1, P2, P3, and P4. The second light-emitting unit 122 corresponds to the pads P9, P10, P11, and P12. The third light-emitting unit 123 corresponds to the pads P5, P6, P7, and P8. The fourth light-emitting unit 124 corresponds to the pads P13, P14, P15, and P16.

In the embodiment, the driving chip 130 is electrically connected to the pads P1, P2, P3, P4, P5, P6, P7, P8, P9, P10, P11, P12, P13, P14, P15, and P16 of the drive substrate 110. The first pin 131 of the driving chip 130 is electrically connected to the pads P1 and P9 of the drive substrate 110. The second pin 132 of the driving chip 130 is electrically connected to the pads P5 and P13 of the drive substrate 110. The third pin 131a of the driving chip 130 is electrically connected to the pads P2 and P6 of the drive substrate 110. The third pin 133b is electrically connected to the pads P3 and P7 of the drive substrate 110. The third pin 133c is electrically connected to the pads P4 and P8 of the drive substrate 110. The fourth pin 134a of the driving chip 130 is electrically connected to the pads P10 and P14 of the drive substrate 110. The fourth pin 134b is electrically connected to the pads P11 and P15 of the drive substrate 110. The fourth pin 134c is electrically connected to the pads P12 and P16 of the drive substrate 110. That is, each of the pins of the driving chip 130 may be divided into two ways to be electrically connected to two pads.

Furthermore, as shown in FIG. 3, the light-emitting modules 120 of the embodiment further include multiple pads C1, C2, C3, C4, C5, C6, C7, C8, C9, C10, C11, C12, C13, C14, C15, and C16 respectively corresponding to the pads P1, P2, P3, P4, P5, P6, P7, P8, P9, P10, P11, P12, P13, P14, P15, and P16 on the drive substrate 110. The light-emitting modules 120 are electrically connected to the drive substrate 110 with surface-mount technology (SMT). The first light-emitting unit 121 has the pads C1, C2, C3, and C4. The second light-emitting unit 122 has the pads C9, C10, C11, and C12. The third light-emitting unit 123 has the pads C5, C6, C7, and C8. The fourth light-emitting unit 124 has the pads C13, C14, C15, and C16.

The first end R1 of the three light-emitting elements LE of the first light-emitting unit 121 and the first end R1 of the three light-emitting elements LE of the second light-emitting unit 122 are electrically connected to the first pin 131 of the driving chip 130 through the pads C1 and C9 and the pads P1 and P9. The first end R1 of the three light-emitting elements LE of the third light-emitting unit 123 and the first end R1 of the three light-emitting elements LE of the fourth light-emitting unit 124 are respectively electrically connected to the second pin 132 of the driving chip 130 through the pads C5 and C13 and the pads P5 and P13. In the first light-emitting unit 121 and the third light-emitting unit 123, the second end R2 of each of the light-emitting elements LE emitting light with the same color is electrically connected to the three third pins 133a, 133b, and 133c of the driving chip 130. For example, in the first light-emitting unit 121 and the third light-emitting unit 123, the second ends R2 of the red light-emitting diodes R emitting red light are respectively electrically connected to the third pin 133a of the driving chip 130 through the pads C2 and C6 and the pads P2 and P6. In the same way, in the first light-emitting unit 121 and the third light-emitting unit 123, the second ends R2 of the green light-emitting diodes G emitting green light are respectively electrically connected to the third pin 133b of the driving chip 130 through the pads C3 and C7 and the pads P3 and P7. In the first light-emitting unit 121 and the third light-emitting unit 123, the second ends R2 of the blue light-emitting diodes B emitting blue light are respectively electrically connected to the third pin 133c of the driving chip 130 through the pads C4 and C8 and the pads P4 and P8.

In the second light-emitting unit 122 and the fourth light-emitting unit 124, the second end R2 of each of the light-emitting elements LE emitting light with the same color is electrically connected to the fourth pins 134a, 134b, and 134c of the driving chip 130. For example, in the second light-emitting unit 122 and the fourth light-emitting unit 124, the second ends R2 of the red light-emitting diodes R emitting red light are respectively electrically connected to the fourth pin 134a of the driving chip 130 through the pads C10 and C14 and the pads P10 and P14. In the same way, in the second light-emitting unit 122 and the fourth light-emitting unit 124, the second ends R2 of the green light-emitting diodes G emitting green light are respectively electrically connected to the fourth pin 134b of the driving chip 130 through the pads C11 and C15 and the pads P11 and P15. In the second light-emitting unit 122 and the fourth light-emitting unit 124, the second ends R2 of the blue light-emitting diodes B emitting blue light are respectively electrically connected to the fourth pin 134c of the driving chip 130 through the pads C12 and C16 and the pads P12 and P16.

Through the design of the light-emitting modules 120, when each of the light-emitting elements LE of one of the light-emitting unit is damaged, the light-emitting unit can still function to emit light. For example, when an electrical connection interface of the pad C2 of the red light-emitting diode R of the first light-emitting unit 121 and the corresponding pad P2 of the drive substrate 110 is damaged, the red light-emitting diode R of the first light-emitting unit 121 can still emit light since the second end R2 of the red light-emitting diode R of the third light-emitting unit 123 is electrically connected to the second end R2 of the red light-emitting diode R of the first light-emitting unit 121 with another wire. When an electrical connection interface of the pad C1 of the first light-emitting unit 121 and the corresponding pad P1 of the drive substrate 110 connected to the same electrode is damaged, the red light-emitting diode R, the green light-emitting diode G, and the blue light-emitting diode B in the first light-emitting unit 121 can still emit light since another wire on the same electrode of the first end R1 of the red light-emitting diode R, the first end R1 of the green light-emitting diodes G, and the first end R1 of the blue light-emitting diodes B of the second light-emitting unit 122 is electrically connected to the same electrode of the first end R1 of the red light-emitting diode R, the first end R1 of the green light-emitting diodes G, and the first end R1 of the blue light-emitting diodes B of the first light-emitting unit 121. Based on the above, even when the electrical connection interfaces of the pads C1, C2, C3, and C4 of the first light-emitting unit 121 and the corresponding pads P1, P2, P3, and P4 are all damaged, the first light-emitting unit 121 can still emit light.

Note that, as shown in FIG. 2A, in the light-emitting modules 120 of the embodiment, each of the light-emitting units are protected by two-way circuits, so the interface damage of the pads and the corresponding pads of one of the two different sets of light-emitting units connected to the same electrode is tolerated at most in each of the light-emitting modules. Here, the two different sets of the light-emitting units connected to the same electrode are, for example, the first light-emitting unit 121 and the third light-emitting unit 123, or the second light-emitting unit 122 and the fourth light-emitting unit 124. In brief, through the design above, when the light-emitting elements LE in the light-emitting units are damaged due to collisions or solder cracks, the light-emitting elements LE can still keep emitting light so as to enhance the protection of the light-emitting modules 120 and reduce the rate of pixel malfunctioning and effectively reduce the repair rate for the light-emitting modules 120. As a result, the service life of the display device 100 of the embodiment may be increased.

In light of the above, the embodiment of the disclosure has at least one of the following advantages or effects. In the design of the light-emitting modules of the disclosure, each of the light-emitting units of the light-emitting modules is protected by two-way circuits with the design of the first ends of the light-emitting elements of the first light-emitting unit and the second light-emitting unit among the light-emitting units being electrically interconnected, the first ends of the light-emitting elements of the third light-emitting unit and the fourth light-emitting unit among the light-emitting units being electrically interconnected, the second end of one of the light-emitting elements of the first light-emitting unit and the second end of one of the light-emitting elements of the corresponding third light-emitting unit being electrically interconnected, and the second end of one of the light-emitting elements of the second light-emitting unit and the second end of one of the light-emitting elements of the corresponding fourth light-emitting unit being electrically interconnected. Hence, when one of the two different sets of light-emitting units connected to the same electrode is damaged, the overall functionality of the light-emitting modules remains unaffected. Accordingly, the protection of the light-emitting modules of the disclosure is enhanced so as to reduce the rate of pixel malfunctioning and effectively reduce the repair rate.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A light-emitting module, comprising a plurality of light-emitting units, wherein:
each of the light-emitting units comprises a plurality of light-emitting elements, each of the light-emitting elements comprises a first end and a second end,
wherein the first ends of the light-emitting elements of a first light-emitting unit and a second light-emitting unit among the light-emitting units are electrically interconnected, the first ends of the light-emitting elements of a third light-emitting unit and a fourth light-emitting unit among the light-emitting units are electrically interconnected, the second end of one of the light-emitting elements of the first light-emitting unit and the second end of one of the light-emitting elements of the corresponding third light-emitting unit are electrically interconnected, and the second end of one of the light-emitting elements of the second light-emitting unit and the second end of one of the light-emitting elements of the corresponding fourth light-emitting unit are electrically interconnected.

2. The light-emitting module according to claim 1, wherein the first end is a p-electrode and the second end is an n-electrode.

3. The light-emitting module according to claim 1, wherein the first end is an n-electrode and the second end is a p-electrode.

4. The light-emitting module according to claim 1, wherein the light-emitting elements comprise a red light-emitting diode, a blue light-emitting diode, and a green light-emitting diode.

5. The light-emitting module according to claim 1, wherein the first light-emitting unit and the second light-emitting unit are adjacently configured, and an arrangement direction of the first light-emitting unit and the third light-emitting unit is parallel to an arrangement direction of the second light-emitting unit and the fourth light-emitting unit.

6. A display device, comprising a drive substrate and a plurality of light-emitting modules, wherein:
the light-emitting modules are configured on the drive substrate and electrically connected to the drive substrate, each of the light-emitting modules comprises a plurality of light-emitting units, wherein:
each of the light-emitting units comprises a plurality of light-emitting elements, each of the light-emitting elements comprises a first end and a second end,
wherein the first ends of the light-emitting elements of a first light-emitting unit and a second light-emitting unit among the light-emitting units are electrically interconnected, the first ends of the light-emitting elements of a third light-emitting unit and a fourth light-emitting unit among the light-emitting units are electrically interconnected, the second end of one of the light-emitting elements of the first light-emitting unit and the second end of one of the light-emitting elements of the corresponding third light-emitting unit are electrically interconnected, and the second end of one of the light-emitting elements of the second light-emitting unit and the second end of one of the light-emitting elements of the corresponding fourth light-emitting unit are electrically interconnected.

7. The display device according to claim 6, further comprising:
a driving chip comprising a first pin, a second pin, a plurality of third pins, and a plurality of fourth pins, wherein
the first end of each of the light-emitting elements of the first light-emitting unit and the first end of each of the light-emitting elements of the second light-emitting unit are electrically connected to the first pin of the driving chip;
the first end of each of the light-emitting elements of the third light-emitting unit and the first end of each of the light-emitting elements of the fourth light-emitting unit are electrically connected to the second pin of the driving chip;
in the first light-emitting unit and the third light-emitting unit, the second end of each of the light-emitting elements emitting light with the same color is electrically connected to each of the third pins of the driving chip; and
in the second light-emitting unit and the fourth light-emitting unit, the second end of each of the light-emitting elements emitting light with the same color is electrically connected to each of the fourth pins of the driving chip.

8. The display device according to claim 6, wherein the drive substrate comprises a plurality of pads, each of the first light-emitting unit, the second light-emitting unit, the third light-emitting unit, and the fourth light-emitting unit respectively corresponds to four pads among the pads.

9. The display device according to claim 6, wherein the first end is a p-electrode and the second end is an n-electrode.

10. The display device according to claim 6, wherein the first end is an n-electrode and the second end is a p-electrode.

11. The display device according to claim 6, wherein the light-emitting elements comprise a red light-emitting diode, a blue light-emitting diode, and a green light-emitting diode.

12. The display device according to claim 6, wherein the first light-emitting unit and the second light-emitting unit are adjacently configured, and an arrangement direction of the first light-emitting unit and the third light-emitting unit is parallel to an arrangement direction of the second light-emitting unit and the fourth light-emitting unit.

13. The display device according to claim 6, wherein the drive substrate comprises a printed circuit board.
